(19) United States
(12) Patent Application Publication
(10) Pub. No.: US 2023/0273522 A1
(43) Pub. Date: Aug. 31, 2023

(54) METHOD AND APPARATUS FOR ALIGNING ARRAYS OF OPTICAL FIBERS

(71) Applicant: Soreq Nuclear Research Center, Yavne (IL)

(72) Inventors: Bruno Sfez, North Ogden, UT (US); Neta Arad-Vosk, Yavne (IL); Netanel Malka, Yavne (IL)

(73) Assignee: Soreq Nuclear Research Center, Yavne (IL)

(21) Appl. No.: 18/006,904

(22) PCT Filed: Jul. 29, 2021
(86) PCT No.: PCT/IB2021/056901

§ 371 Date: Jan. 26, 2023

Related U.S. Application Data
(60) Provisional application No. 63/057,898, filed on Jul. 29, 2020.

(51) Int. Cl. G03F 7/11; G02B 6/36; G03F 7/00

(52) U.S. Cl. CPC G03F 7/11; G02B 6/3652; G02B 6/3672; G02B 6/3684; G03F 7/0005; G03F 7/0015

(57) ABSTRACT

A method for manufacturing an array of optical fiber ferrules includes producing on a first side of a wafer a pattern of an array of disks or holes (111, 112) in a metallic coating (121, 122). The metallic coating is covered with a negative photoresist layer. A second side of the wafer opposite to the first side is illuminated with light that propagates as a divergent or collimated beam through the photoresist layer, thereby creating a conical pattern within the photoresist layer. The photoresist layer is developed to create conical apertures. A sheet with a conical openings pattern registered to the conical apertures is attached so that a small diameter of each conical opening of the sheet is smaller than, and in contact with, a large diameter of the conical aperture to which it is registered, thereby forming an array of optical fiber ferrules.

### FIELD OF THE INVENTION

The present invention relates to a method for manufacturing an expanded beam connector for fiber arrays, including arbitrary ordering of the array (not necessarily linear array or square array). It consists in a lithography-based fabrication of a ferrules array and a wafer-level assembly.

### BACKGROUND OF THE INVENTION

Optical fiber connectivity requires high alignment precision. If the fibers are multimode, this precision can be obtained by so-called passive alignment, meaning that the alignment procedure does not require closed loop feed-back on the alignment quality measurement. The precision needed is in general in the several microns range and can be obtained by a pick-and-place procedure. However, when the connectivity of single-mode fibers is required, the situation is more complex. In the general case, active alignment is necessary (for example, alignment of a single-mode fiber to a free-space laser). However, in the case of single-mode connectors for single fibers, the technique employed is a combination of a sleeve and a ferrule. The ferrule and the sleeve are fabricated with a high precision (in the order of better than half a micron). The single-mode fiber is inserted within the ferrule, and two ferrules (corresponding to the two fibers that may be connected) are inserted within the same precisely machined sleeve. By providing long enough sleeves and ferrules, it is possible to precisely align the two fibers.

This method however is ill-suited for fiber connection in a dirty environment since a particle of a few microns can block the access to the fiber cores and generate large losses. It is obviously even more complex to align an array of such fibers. In order to deal with this problem, a common approach is to make use of microlenses whose focal points are at the fiber facets, leading to large beams that are much less sensitive to small dirt particles (so-called expanded beam connector). In addition, the alignment of two such expanded beam connectors is much less sensitive to small translational errors. However, this comes at the price of a very high sensitivity to angular alignment errors. This sensitivity can be reported to the connector itself, which is more complex to manufacture due to complex active alignment procedures that are both expensive and time consuming. Multiple single-mode fibers expanded connectors are considerably more complex to develop since in addition to the precise parallelism between the fiber facets, it is necessary to ensure parallelism between the fibers, compactness, multiple parallel connections and field operation. Assembly of commercial ferrules or sleeves leads to a large pitch array, which is not suitable in many situations. Other constraints include the possibility of replacing defective fiber, easy mounting of the fibers within the array and so on.

### SUMMARY OF THE INVENTION

The present invention seeks to provide a method for manufacturing an expanded beam connector for fiber arrays, including arbitrary ordering of the array (not necessarily linear array or square array). It consists in a lithography-based fabrication of a ferrules array and a wafer-level assembly, as is described more in detail hereinbelow.

There is provided in accordance with a non-limiting embodiment of the invention a method for manufacturing an array of optical fiber ferrules including producing on a first side of a wafer a pattern of an array of disks or holes in a metallic coating, wherein a diameter of each of the disks or holes is equal to or greater than a diameter of an optical fiber, covering the metallic coating with a negative photoresist layer, illuminating a second side of the wafer opposite to the first side, the second side not being covered by the metallic coating, with light that propagates as a divergent or collimated beam through the photoresist layer, thereby creating a conical pattern within the photoresist layer, developing the photoresist layer to create conical apertures in the photoresist layer, and attaching a sheet with a conical openings pattern registered to the conical apertures in such a way that a small diameter of each conical opening of the sheet is smaller than, and in contact with, a large diameter of the conical aperture to which it is registered, thereby forming an array of optical fiber ferrules.

The angle of the divergent beam may be modified by controlling a numerical aperture of the illumination. Filling the voids may be done by immersing the wafer in an electroforming solution and the voids may be filled with metal that is electroformed.

The conical apertures may be conformally coated with a metallic coating. The metallic coating may be based on nickel. The conical apertures may be conformally coated with polytetrafluoroethylene.

The method may further include introducing an optical fiber in one of the optical fiber ferrules.

The method may further include stacking several the photoresist layers in order to obtain a cascade of conical apertures with decreasing apertures.

A method for manufacturing an optical fiber array includes producing an array of ferrules as described above and herein, coupling a space wafer to the array of ferrules (e.g., aligning and attaching a stop wafer to the array of ferrules, aligning and attaching a spacer wafer to the stop wafer), inserting a wedge in each of the openings of the spacer wafer, attaching a wafer of microlenses arrays to the spacer wafer, attaching an additional spacer wafer and a window to the spacer wafer to form a wafer assembly, and separating the wafer assembly into arrays.

### BRIEF DESCRIPTION OF THE DRAWINGS

The present invention will be understood and appreciated more fully from the following detailed description, taken in conjunction with the drawings in which:

FIG. 1 is a simplified illustration of a transparent wafer, such as a glass wafer, which is metal coated (121, 122) and patterned with an array of transparent holes (112) or through-holes (111), in accordance with a non-limiting embodiment of the invention.

FIG. 2 is a simplified illustration of a wafer after photoresist deposition, in accordance with a non-limiting embodiment of the invention. 201 is a liquid photoresist layer that fills the holes in the wafer. Then a SUEX (from DJ Microlaminates Inc.) photoresist sheet 203 is laminated. 202 is directly a SUEX sheet laminated on the wafer (transparent holes).

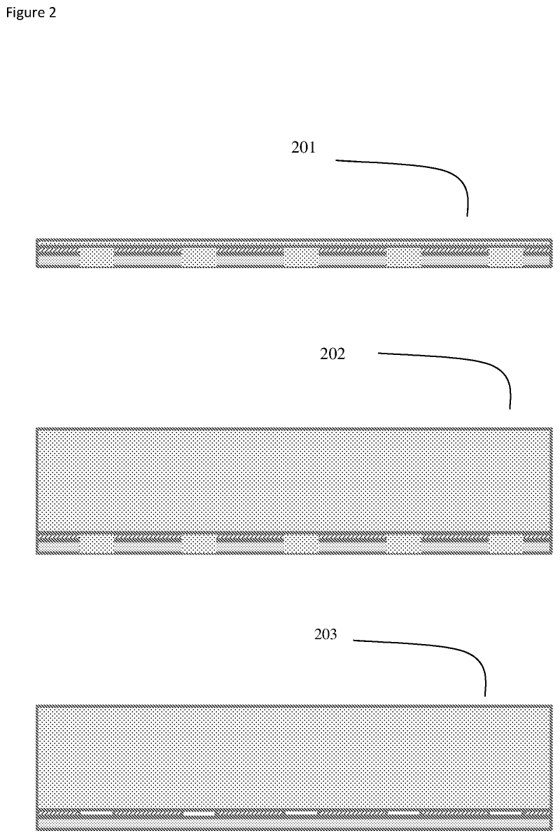

FIG. 3 is a simplified illustration of UV light illuminating the wafer from the side not covered with photoresist, in accordance with a non-limiting embodiment of the invention. Light (301) is blocked by the metallic coating except where there are transparent apertures. 302 is the angle of the light cone with the wafer surface.

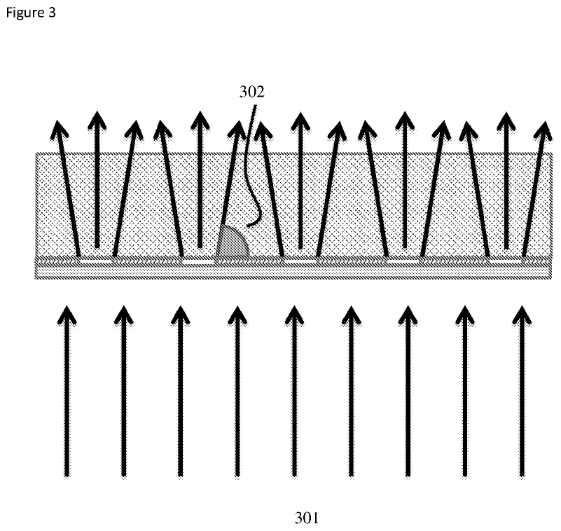

FIG. 4 is a simplified illustration of the wafer after development. The wafer is covered with inverted pyramids or cones made from photoresist.

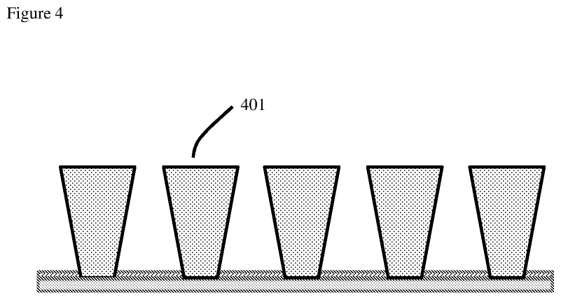

FIG. 5 is a simplified illustration of the wafer covered with a metallic layer, after an electroforming process. 501 and 502 represent the metallic filling between the photoresist pyramids, which will then constitute the body of the insert. 501 is before photoresist removal and 502 after.

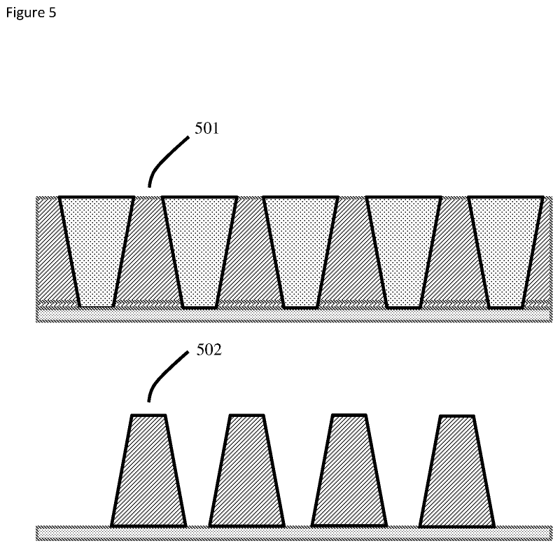

FIG. 6 is a simplified illustration of the structure, and shows the insert after a mechanically processed metallic part 601 is attached to the wafer structure. 602 is the diameter of the empty space near the wafer, 603 the diameter of the metallic structure that has been processed in the lithographic process at the attachment region, and 604 the diameter of the metallic structure that has been processed mechanically at the attachment region.

FIG. 7 is a simplified illustration of 701, which is a holed wafer that acts as a precise spacer.

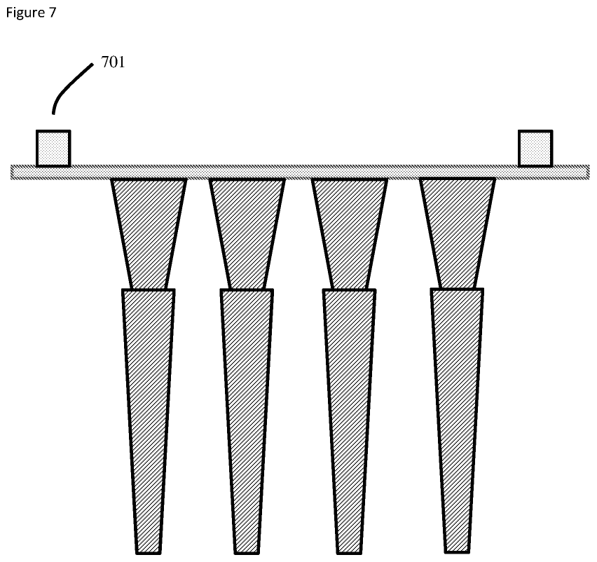

FIG. 8 is a simplified illustration of 801, which is an array of wedges that emulate angle cleaving, 802, which is a microlenses array and 803, which is a protective transparent wafer.

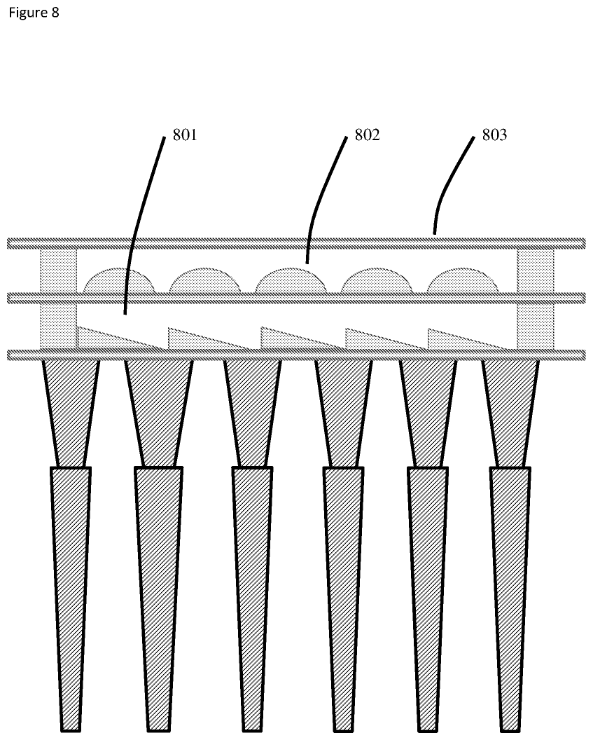

FIG. 9 is a simplified illustration of the wafer assembly cut into pieces (inserts).

FIG. 10 is a simplified illustration of the body 1001 of the connector, which is also part of the final alignment procedure.

FIG. 11 is a simplified illustration of the final alignment procedure. The insert 1101 is introduced within the connector body 1001. The connector body lies on a flat surface 1103 on which a flat block 1104 is also laying. Alignment is provided by pressing the insert against two perpendicular walls.

FIG. 12 is a simplified illustration of a prism 1201, which is attached to the external window of the insert in order to compensate for the angle created by the wedge array.

FIG. 13 is a simplified illustration of two connected connectors with fibers 1301 in accordance with a non-limiting embodiment of the invention.

FIG. 14 is a simplified illustration of a glass wafer A111 which is metal coated and patterned with an array of metallic disks (A112). The patterned region (A113) represents the continuing wafer.

FIG. 15 is a simplified illustration of a SUEX photoresist sheet A203 laminated on the patterned wafer.

FIG. 16 is a simplified illustration of UV light illuminating the wafer from the side not covered with photoresist. UV light (A301) is blocked by the metallic coating except where there are transparent apertures. The arrows indicate the regions where the light is passing through.

FIG. 17 is a simplified illustration of light passing through the photoresist, which is absorbed, so the light intensity decreases while passing through the photoresist, as indicated by the gray levels (whiter means higher light exposure). This effect modifies the etching boundary.

FIG. 18 is a simplified illustration of the obtained shape, after development, which is an array of conical apertures (A401). Upper figure: cross-section, lower figure view from above. A few apertures (A402) are added to the mask for future alignment procedures.

FIG. 19 is a simplified illustration of the SUEX photoresist removed from the patterned glass substrate, leaving a rigid sheet of with conical through-holes.

FIG. 20 is a simplified illustration of two optical fibers A602 introduced through the funneling holes of the photoresist layer A601 (thickness: 1 mm)

FIG. 21 is a simplified illustration of several layers A701, similar to FIG. 19, which can be fabricated with slightly different parameters and stacked one on top of the other in order to provide a higher funneling effect.

FIG. 22 is a simplified illustration of the different layers aligned, either at the chip level or the wafer level, using precise pins A801 that are inserted in the lithographically defined holes A402.

FIG. 23 is a simplified illustration of a stop layer made of a lithographically defined array of holes of diameter slightly smaller than the fibers diameter so that APC fibers are partly inserted in these holes and are blocked at a predefined penetration depth.

FIG. 24 is a simplified illustration of different layers (the ferrules, the stop layer, the micro-lens array) stacked one on top of the other, with precise spacers between them, and aligned using the pins A801 from FIG. 22. A prism compensates for the angular deviation generated by the angle polished fibers termination. It is not part of the stacking but part of the connector casing.

FIG. 25 is a simplified illustration of the embodiment of FIG. 24, showing the fibers inserted and stopped by the stop layer.

FIG. 26 is a simplified illustration of an additional pattern. In addition to the patterns directly related to the connector, such as the disks patterning, for example, shown in the previous figures, an additional pattern can be added, so that the wafer can be easily separated into connector elements. Once the layers have been stacked and glued, the individual parts can be easily separated using minimal mechanical pressure.

### DETAILED DESCRIPTION OF THE INVENTION

The following is a non-limiting description of manufacturing the ferrules array.

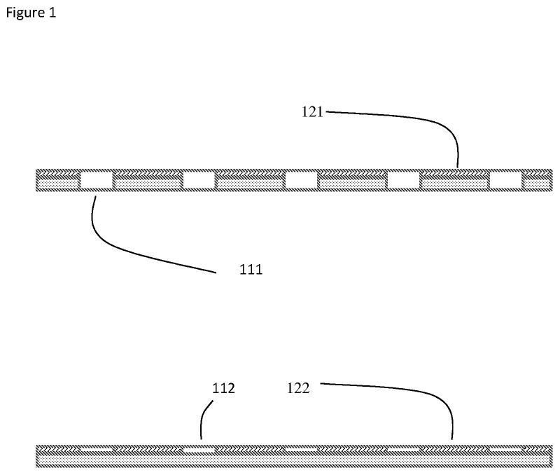

First, the fabrication of the ferrules array wafer is described, and assumes that 200-300 nm resolution lithography is available. In the first stage (FIG. 1), a transparent wafer (for example, glass) is patterned with an array of transparent holes 111/112 in a metallic coating 121/122. The diameter of the holes, d1, is equal to the diameter of the fiber, d_f, in addition to the tolerance of the lithography process, t_lith. For example, if the two-sigma maximum fiber diameter d_f=126 microns, then the hole diameter will be 126.2 microns for a lithographic tolerance of t_lith=200 nm. These holes can be transparent areas on the wafer (112 and 122) or through-holes (111 and 121).

The metallic coating is then covered with a negative photoresist such as SU8 photoresist. The thickness of the photoresist should be at least above 100 microns.

In the case of holed apertures (111) this can be obtained through spin-coating of liquid SU8 photoresist (201) (from Microchem Inc.), followed by lamination of SUEX thick sheets (202). In the case of transparent apertures in the glass substrate (112) this can be obtained directly through lamination of the SUEX sheets (203).

Then a uniform illumination (e.g., UV light 301) is provided on the back side of the wafer (the side that is not covered by the metallic coating) so that UV light is transmitted only through the holes (and is blocked by the metallic coating). Following the holes, light propagates according to divergent beams (one beam per hole), therefore creating a conical illumination pattern within the photoresist layer. The exact angle (302) of this conical pattern can be modified by controlling the numerical aperture of the UV illumination. The angle is chosen to be close enough to 90° so as to reduce friction as much as possible and ultimately ensure smooth gliding of the fiber inside the ferrule.

Following this illumination pattern, the photoresist is exposed, leaving inverted conical structures 401 in the photoresist layer. Between these structures the wafer is covered with the initial metallic thin coating 121/122. Then the wafer is immersed in an electroforming solution and the voids between the conical structures may be filled with metal that is electroformed (501). In order to improve the process, it is possible to first conformally coat the inverted SU8 conical structures with a metallic coating (for example using an atomic layer deposition technique) so that the inverted conical columns are entirely coated with metal.

Then the photoresist is removed, leaving conical apertures in a thick metallic layer 502. The small conical diameter 602 is d1=d_f+d_lith (the size of the holes opening), and the large conical diameter 603 is d2=d1+2T·tan(α), where T is the metallic layer thickness and a the angle of the walls with the normal to the wafer.

Then a metallic block of at least a few millimeters thick (601) is prepared with conical holes spatially arranged according to the pattern of holes described above, and whose small diameter 604 (including the manufacturing tolerance t_m and passive alignment tolerance t_a) lies between d1 and d2.

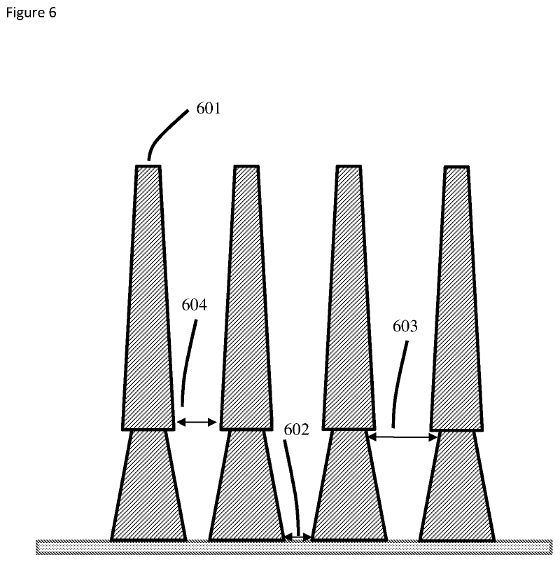

The large diameter is chosen so that an optical fiber can be easily introduced in the opening. This block is then passively aligned and attached to the wafer so that the axes of the conical apertures coincide (see FIG. 6). The attachment can be obtained using adhesive materials, pins in the metal part that are inserted to holes in the lithographic part or through a fusion process (metal to metal).

The divergence of the UV illumination may be chosen so that the aperture diameter at the outer metallic surface of the wafer 603 is a least a few microns larger than the aperture diameter at the wafer surface itself 602, and a, the angle between the walls and the normal to the wafer surface, is very small.

A slippery coating, such as polytetrafluoroethylene coating, can then be deposited conformally so that the walls of the conical apertures have a very low friction coefficient.

Accordingly, an optical fiber can be introduced in the outer opening of the metallic layer and is guided by the walls, first roughly (in the outer metallic layer) and then precisely (in the inner metallic layer). In the alternative where the holes in the substrate are through holes, the fibers that passed through both cones can be then cleaved and polished. The fibers are maintained in place either by using an adhesive layer between the fiber and the substrate, by filling the conical aperture with an adhesive material, by laser soldering the fiber and the substrate, by mechanically pressing the fiber against the wafer, or by mechanically gripping the fiber. A thin layer of index-matched oil can be introduced between the fiber and the wafer for better optical contact.

Having detailed the structure of the ferrules array wafer, an example for the whole connector structure is now presented. The connector may be manufactured using the so-called wafer-level assembly technology, where the whole structure is obtained by precisely aligning patterned wafers (of the same size), attaching them one to the other and then dicing them into individual devices. The advantage of this rapidly growing technology is that most active alignments procedures are performed at the wafer level, simultaneously for multiple devices, rather than for each device individually. Furthermore, this active alignment can be replaced by passive alignment of wafers with special 3D patterns that lock one into the other.

First, a patterned array geometry may be defined. The description follows for the non-limiting example of a five-by-five fibers array connector. The pitch of the array is 1 mm. The wafer is patterned with such arrays. For example, taking the preceding example, the ferrules arrays wafer is patterned with arrays of 5-by-5 disks with a pitch of 1 mm and a diameter of 126 microns. The pitch of the arrays (arrays center-to-center distance) is set to 8 mm in this example in both directions.

Following the procedure described above, a ferrules arrays wafer is prepared. Then a spacer wafer 701 is prepared. The spacer wafer is a wafer with holes in the exact position of the array. In our example, this wafer has square openings of 6 mm by 6 mm with a pitch identical to the pitch of the ferrules array wafer (8 mm). This wafer is then passively aligned and attached to the ferrules array wafer.

Next, a one-dimensional array of wedges 801 is inserted in the openings of the previous spacer wafer. The objective of this array is to emulate angle cleaved fibers. The procedure described above does not easily adapt to angle-cleaved fibers, so the fibers may be attached when their facet is parallel to the ferrules' arrays wafer. This causes a problem for back reflection. In order to remediate to this problem, an array of wedges may be added that disperses the light beams like angle-cleaved fibers. The wedge angle can be set to 8°, as the angle-cleaved fibers angle.

Each array of wedges can be individually placed in the openings (the positioning precision is around 100 microns, so pick-and-place techniques are sufficient) and attached to the ferrules arrays wafer. The spacer wafer may be chosen thick enough so that the top of the wedges is below the upper surface of the spacer wafer.

Next a wafer of microlenses arrays 802 is attached to the spacer wafer. The positioning of this wafer can be done actively using a small number of reference points. For example, three fibers can be attached at the ferrules array periphery, far one from the other, and light coupled in. At the output, a retroreflector is positioned and light that is reflected back is coupled back in the fiber if the microlenses arrays are aligned. By monitoring light that comes back from the fiber (using for example a circulator), it is possible to optimize the microlenses arrays alignment. The wafers are then attached one to the other.

An additional spacer wafer 803 is attached to the assembly and a window is attached to this spacer wafer. The wafer assembly is then tested in order to identify defective arrays.

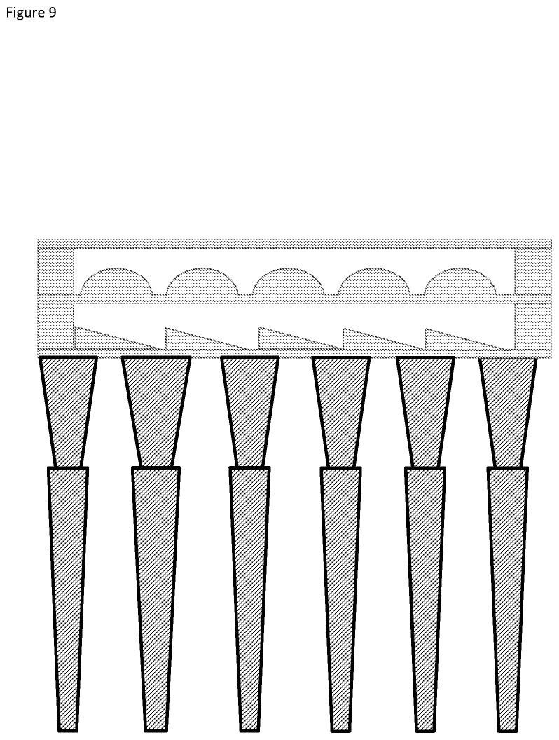

The wafers assembly is then diced into 6 mm×6 mm arrays (inserts), and defective elements are discarded (FIG. 9).

The last part of the assembly is the insertion of the previously described insert into a metallic enclosure. The beams that exit the insert have a large diameter. Therefore, their tolerance to translational assembly errors is large but they are very sensitive to angular assembly errors. The following describes how to take advantage of this for the final assembly.

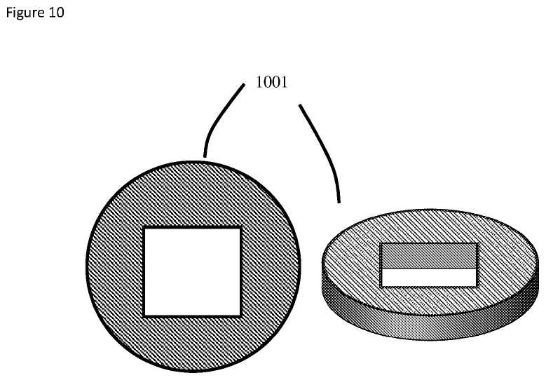

The metallic enclosure 1001 (FIG. 10) has a square opening so that the 6 mm×6 mm element can be inserted mechanically (since the translational tolerance is large). However, the faces of this metallic part may be very flat and parallel (in order to minimize angular assembly errors). This can be obtained using advanced polishing techniques such as electrical discharge machining (EDM). In addition, the enclosure can have an asymmetric pattern (such as a relief and a hole at two different locations of the enclosure) so that two such enclosures are self-aligned when in physical contact.

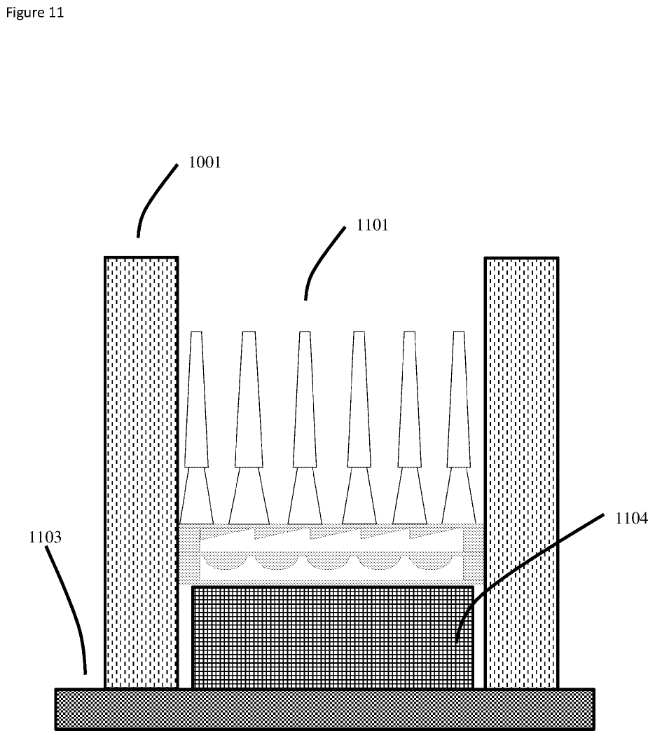

An assembly jig (FIG. 11) is made of a flat wafer 1103 (alignment wafer) and a flat element 1104 whose planar dimensions are slightly smaller than the insert planar dimensions and whose thickness is described below. The metallic enclosure 1001 is put on the flat wafer with the flat element inside the enclosure. The insert is then put in the enclosure, the external window 803 in physical contact with the flat surface of 1104, and pressed against two perpendicular walls of the metallic enclosure 1001. An adhesive is then introduced between the insert and the walls so that temperature changes do not affect the position of the insert relative to the enclosure, as known in the art. It should be noted that all the surfaces parallel to the alignment wafer have tight parallelism and flatness tolerances, which minimizes angular assembly errors, as said before.

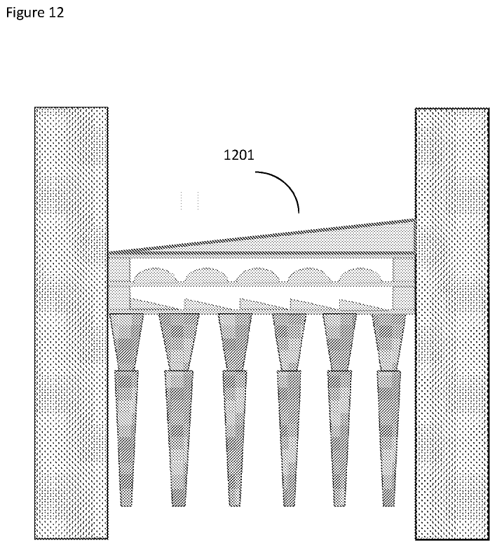

Finally, a single wedge with the same angle as the wedges array described above, and with dimensions of 6 mm by 6 mm is attached to the window so that light exiting the connector is parallel to the connector axis (FIG. 12).

In order to reduce back-reflections, free surfaces may be anti-reflection coated.

The metallic enclosure is then inserted into a spring loaded mount that allows physical contact of the two metallic enclosures.

In order to introduce the fibers, the following procedure can be used. A glass block of the same length and width as the insert is fabricated, with an array of holes corresponding to the array of microlenses. The hole diameter may be larger than the fiber diameter, but does not have to be precise. Then fibers are introduced in the holes and a thick layer of organic liquid material which can be polymerized is deposited on top of the glass block (between the fibers). After polymerization the block is polished and the fibers may be polished with exactly the right length. The glass block is then removed and the fibers introduced in the insert.

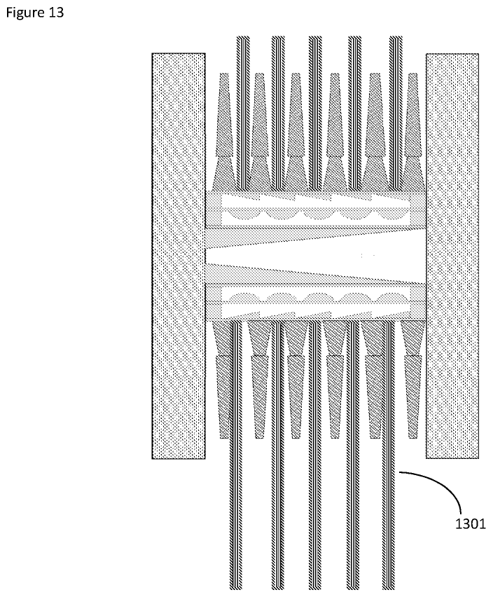

FIG. 13 shows the complete insert with single-mode fibers in place.

An alternative way to form the connector without the electroforming stage is now described.

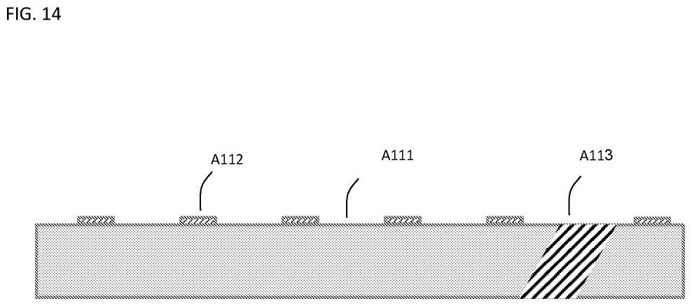

Reference is now made to FIG. 14. On a glass wafer A111, a pattern of metallic discs A112 are generated, whose diameter is chosen as a function of the fiber diameter. The patterned region A113 represents the continuing wafer.

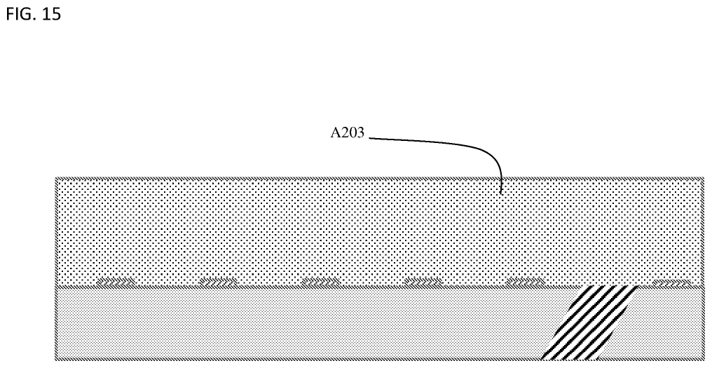

On this wafer, a SUEX photoresist film (or equivalent) A203 is laminated or coated (FIG. 15).

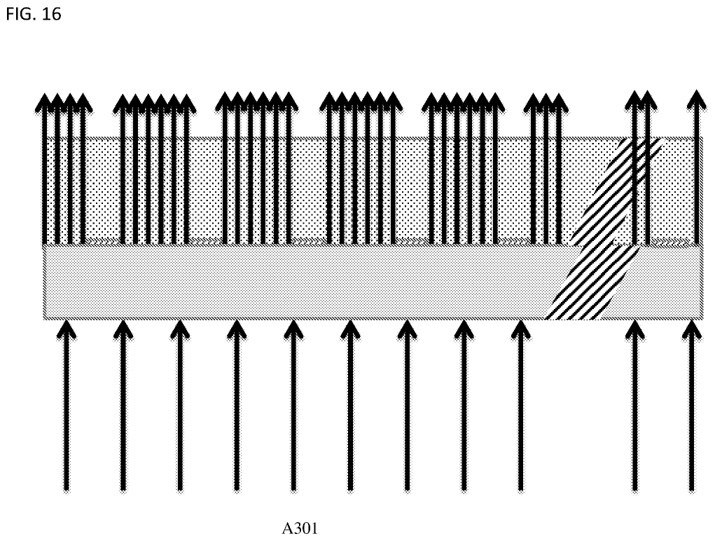

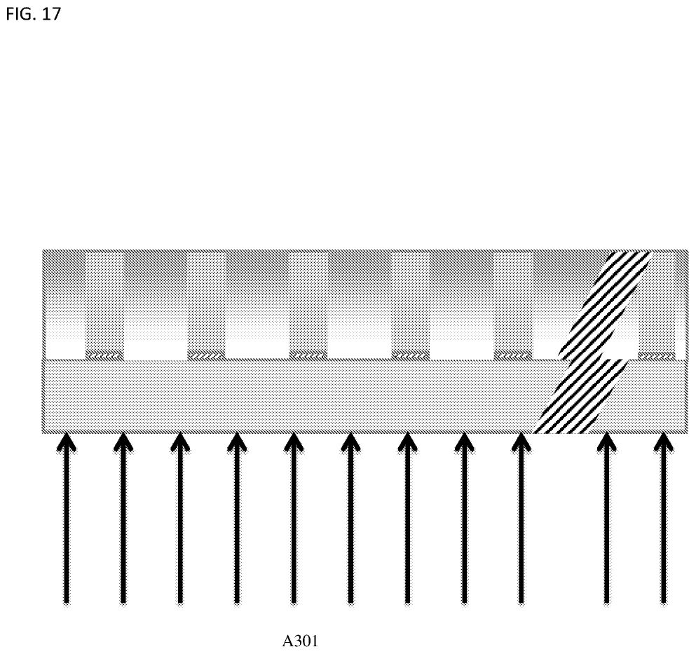

Uniform UV light A301 is then illuminated from the wafer's back side as shown in FIG. 16. When the UV light crosses the photoresist layer, two effects occur. First light is absorbed in the photoresist, resulting in local cross-linking. The second effect is that, because of this absorption effect, the amount of light decreases along the propagation direction, as illustrated in FIG. 17. It might occur therefore that for initial light intensities, A301 is below a certain value, and cross-linking occurs only until a certain depth. This means that chemical etching will occur until a certain depth. If one also takes into account the divergence of the UV light beam (due to a combination of intrinsic divergence and diffraction at the mask boundaries), the obtained pattern after etching will have a conical shape (and not purely cylindrical), the cone angle depending on the exact illumination parameters (intensity, divergence, wavelength etc.).

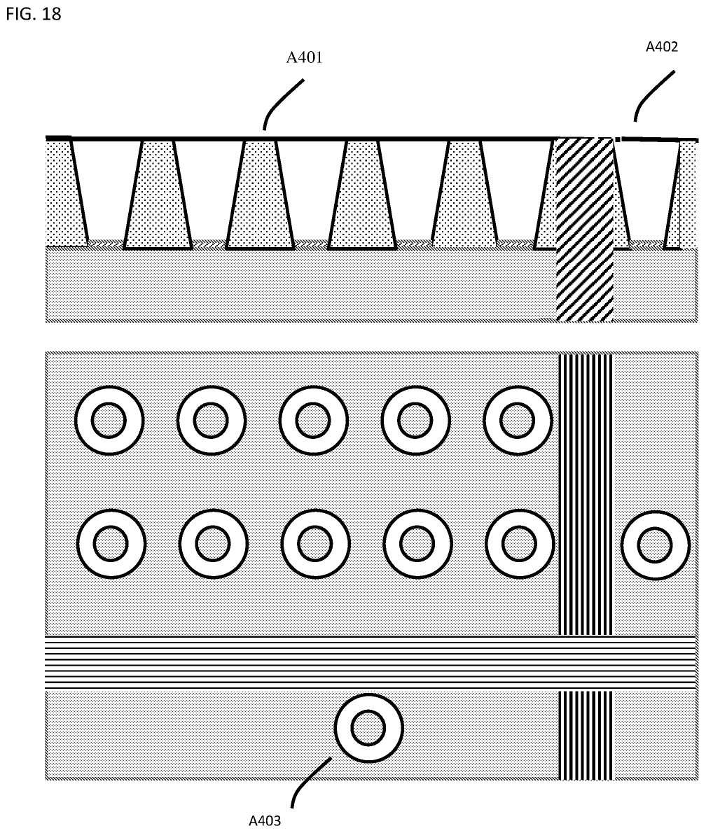

In FIG. 18 such a desired conical pattern A401 is shown. The upper drawing shows a cross section of the wafer and the lower a view from above. Several rows of such conical apertures A401 are prepared. Optionally additional apertures A402 and A403 can be added for assisting in the final precise assembly.

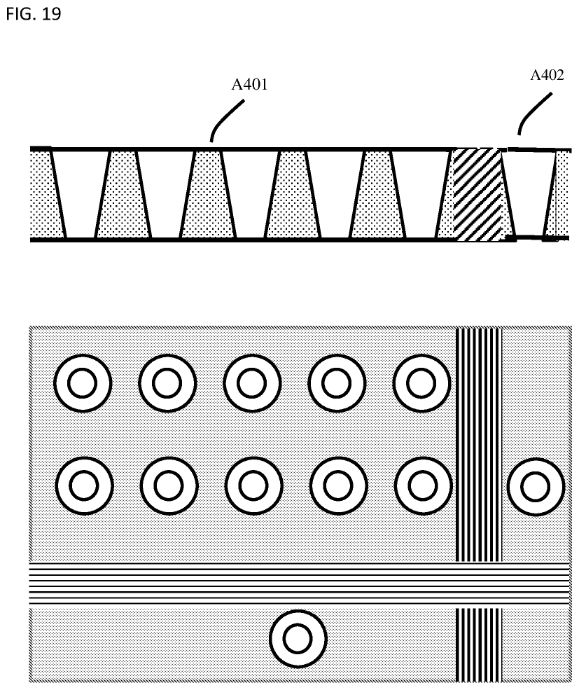

Once the etching has been completed, the cross-linked SUEX layer is peeled off the substrate, resulting in a substrate free structure, as shown in FIG. 19. The conical apertures are now conical through-holes where the bottom diameter is smaller than the top diameter. Compared to a cylindrical through-hole, it is easier to insert the fiber and a better positioning accuracy is obtained. For example, considering a 1 mm thick SUEX layer, and a 126 microns fiber diameter, then getting a 1 degree conical angle leads to a top diameter that is 17 microns larger than the bottom one. Assuming a 200 nm lithographic precision, a bottom diameter of 126.2 microns leads to a top diameter of 143.2 microns. Inserting the fiber is therefore greatly simplified.

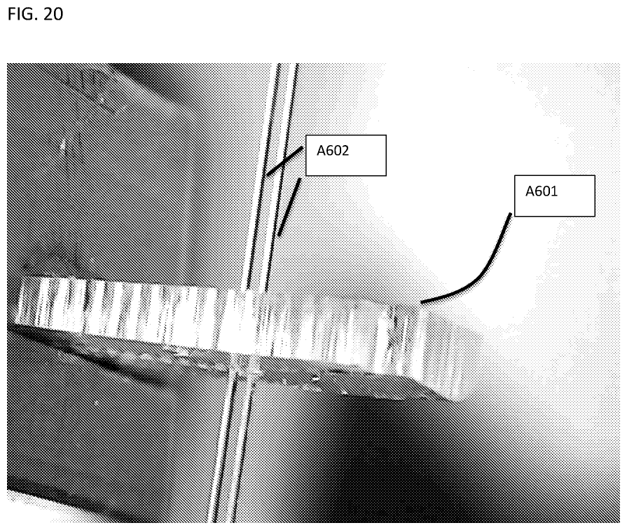

FIG. 20 shows two optical fibers that have been experimentally inserted in a layer with dimensions similar to the said example.

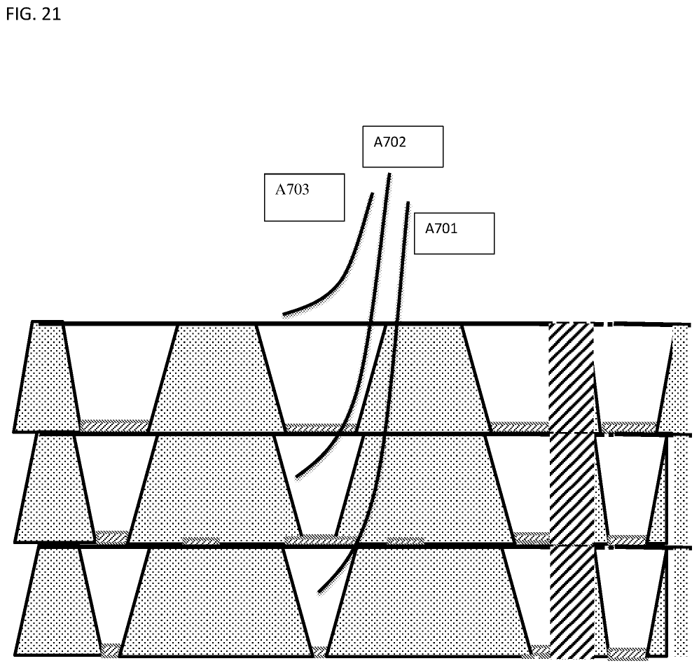

FIG. 21 shows the possibility of stacking such layers, therefore providing increased insertion simplification. The stack is formed in such a way that the top aperture diameter of layer A701 is larger than the bottom aperture diameter of layer 702, the top diameter of layer 702 is larger than both the bottom aperture diameter of layer 703 and the top aperture diameter of layer 701, and so on. Each such additional layer simplifies the fiber insertion.

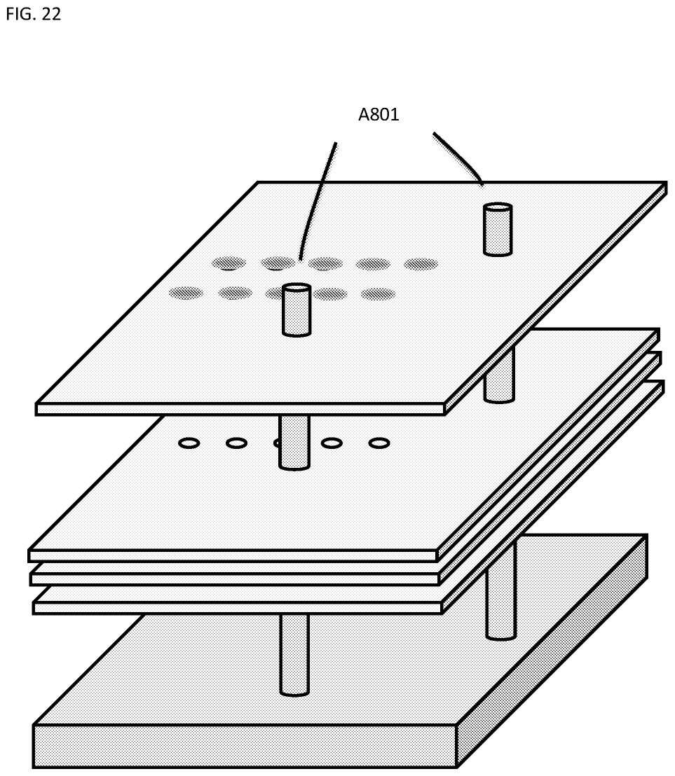

Once the different layers are prepared, they can be stacked one on top of the other, as shown on FIG. 22, using either active alignment techniques or precise positioning pins A801.

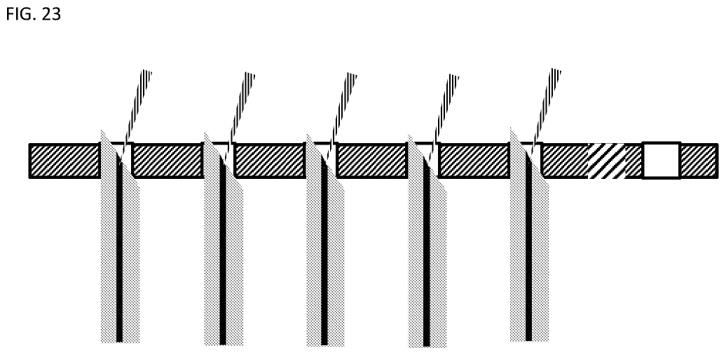

In case of Angle Polished Fibers (APC fibers), the fibers can be inserted until a given depth using a stop layer as illustrated in FIG. 23. The stop layer is made of a lithographically defined array of holes of diameter slightly smaller than the fibers diameter so that APC fibers are partly inserted in these holes and are blocked at a predefined insertion depth.

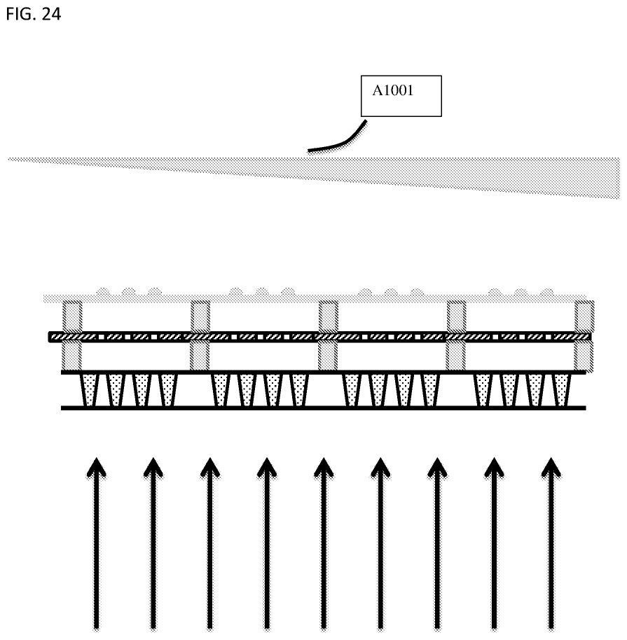

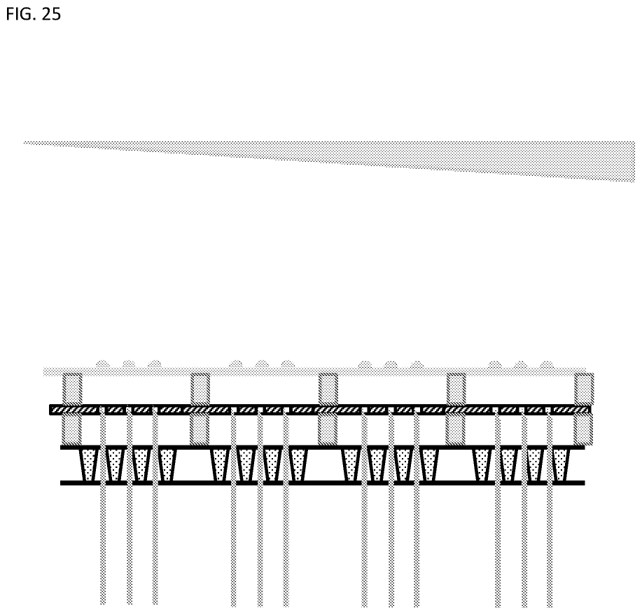

The angle compensation is provided by an additional prism A1001 (FIG. 24), that does not need to be precisely positioned (meaning standard pick and place positioning is enough). Therefore, the light beams exit the connector precisely normal to the connector external facet. FIG. 25 shows the connector with the fibers inserted.

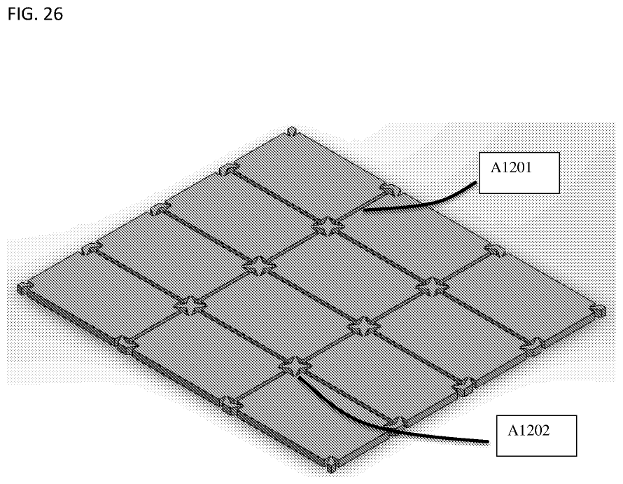

The connector can be assembled at the chip level (single element) or at the wafer level. In such a case it is necessary to separate the different connectors after assembly (and gluing). This can be done using dicing, or alternatively, the wafers can be prepared in advance (at the lithographic stage) so that trenches A1201 are etched between the different connectors of the wafer assembly, and a weak mechanical link A1202 is left for mechanical support, as shown in FIG. 26. A weak (and controllable) pressure is enough to separate the different connectors. It should be noted that since the trenches are prepared lithographically, their position accuracy is in the order of a few hundreds of nanometers.

What is claimed is:

1. A method for manufacturing an array of optical fiber ferrules comprising:
producing on a first side of a wafer a pattern of an array of disks or holes (111, 112) in a metallic coating (121, 122), wherein a diameter of each of said disks or holes is equal to or greater than a diameter of an optical fiber;
covering said metallic coating with a negative photoresist layer;
illuminating a second side of said wafer opposite to said first side, said second side not being covered by the metallic coating, with light that propagates as a divergent or collimated beam through said photoresist layer, thereby creating a conical pattern within said photoresist layer;
developing said photoresist layer to create conical apertures in said photoresist layer; and
attaching a sheet with a conical openings pattern registered to said conical apertures in such a way that a small diameter of each conical opening of the sheet is smaller than, and in contact with, a large diameter of said conical aperture to which it is registered, thereby forming an array of optical fiber ferrules.

2. The method according to claim 1, wherein an angle (302) of said divergent beam is modified by controlling a numerical aperture of the illumination.

3. The method according to claim 1, wherein filling the voids is done by immersing said wafer in an electroforming solution and the voids are filled with metal that is electroformed (501).

4. The method according to claim 1, wherein said conical apertures are conformally coated with a metallic coating.

5. The method according to claim 1, wherein said metallic coating is based on nickel.

6. The method according to claim 1, wherein said conical apertures are conformally coated with polytetrafluoroethylene.

7. The method according to claim 1, further comprising introducing an optical fiber in one of said optical fiber ferrules.

8. The method according to claim 1, wherein said light comprises ultraviolet light.

9. The method according to claim 1, further comprising stacking several said photoresist layers in order to obtain a cascade of conical apertures with decreasing apertures.

10. A method for manufacturing an optical fiber array comprising:
producing an array of ferrules according to claim 1;
inserting a wedge (801) in each of the openings of a spacer wafer (701) coupled to said array of ferrules;
attaching a wafer of microlenses arrays (802) to said spacer wafer (701);
attaching an additional spacer wafer (803) and a window to said spacer wafer (701) to form a wafer assembly; and
separating said wafer assembly into arrays.

11. The method according to claim 10, wherein separating said wafer assembly into arrays is done by dicing said wafer assembly.

12. The method according to claim 10, wherein separating said wafer assembly into arrays is done by etching trenches (A1201) between different connectors of said wafer assembly, so that a breakable mechanical link (A1202) is left for mechanical support, and then breaking said breakable mechanical link (A1202).
